(19) United States
(12) Patent Application Publication
(10) Pub. No.: US 2024/0118161 A1
(43) Pub. Date: Apr. 11, 2024

(54) WAFER CLEANING APPARATUS AND LEAKAGE DETECTION METHOD THEREOF

(71) Applicant: Hon Young Semiconductor Corporation, Hsinchu City (TW)

(72) Inventor: Kuo-Hao PENG, Hsinchu City (TW)

(21) Appl. No.: 18/170,520

(22) Filed: Feb. 16, 2023

(30) Foreign Application Priority Data
Oct. 11, 2022 (TW) 111138469

(51) Int. Cl. G01M 3/18; B08B 3/02; B08B 3/08; B08B 13/00

(52) U.S. Cl. CPC G01M 3/18; B08B 3/022; B08B 3/08; B08B 13/00

(57) ABSTRACT

A wafer cleaning apparatus includes a chamber, a rotary chuck, a liquid spray post, a top lid, a liquid conveying pipeline, a protection pipeline, and a leak sensor. The rotary chuck is located in the chamber, and is configured to attach a wafer cassette. The liquid spray post is located in the chamber. The liquid spray post faces the wafer cassette. The top lid is located on the chamber. The liquid spray post is disposed on the bottom surface of the top lid. The liquid conveying pipeline is located outside the chamber and communicates the liquid spray post, and is disposed along a bottom surface and an external sidewall of the top lid. The protection pipeline sleeves on the liquid conveying pipeline. The leak sensor is located in the protection pipeline, and is located under the lowest section of the liquid conveying pipeline.

### RELATED APPLICATIONS

This application claims priority to Taiwan Application Serial Number 111138469, filed Oct. 11, 2022, which is herein incorporated by reference.

### BACKGROUND

### Field of Disclosure

The present disclosure relates to a wafer cleaning apparatus and a leak detection method of the wafer cleaning apparatus.

### Description of Related Art

Generally, to maintain quality when cleaning the wafer, a liquid conveying pipeline conveying a liquid must have no leakage. If there is leakage, the flow rate of the liquid that enters the chamber may decrease, or the chemical concentration of the liquid may become unstable, which means the apparatus is unable to guarantee the quality of wafer cleaning.

However, due to the high-frequency of opening and closing the lid of the apparatus, some varieties of wafer cleaning apparatus have a problem where the liquid conveying pipeline is folded frequently, and as such, there is a possibility of rupture at the turning sections or the connection points of the pipeline. In addition, these varieties of wafer cleaning apparatus may have a limit on the space above, such that it is impossible to install a flow control valve at the end of the liquid conveying pipeline on the top of the wafer cleaning apparatus to monitor the flow rate that enters the chamber, so that part of the liquid conveying pipeline cannot be monitored. For silicon carbide fabrications, since the cost is significantly higher than silicon fabrication, the demand for the quality of wafer cleaning is also higher.

### SUMMARY

One aspect of the present disclosure provides a wafer cleaning apparatus.

According to one embodiment of the present disclosure, a wafer cleaning apparatus includes a chamber, a rotary chuck, a liquid spray post, a lid, a liquid conveying pipeline, a protection pipeline, and a leak sensor. The rotary chuck is located in the chamber, and is configured to attach a wafer cassette. The liquid spray post is located in the chamber. The liquid spray post faces the wafer cassette. The lid is located on the chamber. The liquid spray post is disposed on the bottom surface of the lid. The liquid conveying pipeline is located outside the chamber and communicates the liquid spray post, and is disposed along a bottom surface of the chamber, an external sidewall of the chamber and the lid. The protection pipeline sleeves on the liquid conveying pipeline. The leak sensor is located in the protection pipeline, and is located under the lowest section of the liquid conveying pipeline.

In some embodiments of the present disclosure, the lowest section of the liquid conveying pipeline is adjacent to a connection point of the bottom surface of the chamber and the external sidewall of the chamber.

In some embodiments of the present disclosure, the liquid conveying pipeline includes a vertical part disposed along the external sidewall of the chamber, and the leak sensor at least partially overlaps with the vertical part of the liquid conveying pipeline in a vertical direction.

In some embodiments of the present disclosure, the liquid conveying pipeline includes a horizontal part disposed along the bottom surface of the chamber, and the leak sensor at least partially overlaps with the horizontal part of the liquid conveying pipeline in a vertical direction.

In some embodiments of the present disclosure, the leak sensor is an impedance leak sensor.

In some embodiments of the present disclosure, the leak sensor is disposed between the liquid conveying pipeline and the protection pipeline.

In some embodiments of the present disclosure, the wafer cleaning apparatus further includes a liquid compounding controlling module connecting a liquid inlet of the liquid conveying pipeline. The liquid compounding controlling module and the leak sensor are located under the bottom surface of the chamber.

In some embodiments of the present disclosure, the liquid compounding controlling module includes a plurality of flow control valves and a plurality of manifold valves, the manifold valves connects the flow control valves respectively, and the manifold valves are located at an upstream of the liquid conveying pipeline and a downstream of the flow control valves.

In some embodiments of the present disclosure, the wafer cleaning apparatus further includes a monitor apparatus electrically connected to the leak sensor and is configured to monitor an impedance value of the leak sensor.

In some embodiments of the present disclosure, the rotary chuck has a rotation axis, the wafer cleaning apparatus further includes a rotating device connected to the rotation axis and configured to rotate the rotary chuck such that the wafer cassette circles around the liquid spray post.

According to another embodiment of the present disclosure, a wafer cleaning apparatus includes a chamber, a rotary chuck, a liquid spray post, a lid, a liquid conveying pipeline, a protection pipeline, and a leak sensor. The rotary chuck is located in the chamber, and is configured to attach a wafer cassette. The liquid spray post is located in the chamber. The liquid spray post faces the wafer cassette. The lid is located on the chamber. The liquid spray post is disposed on the bottom surface of the lid. The liquid conveying pipeline is located outside the chamber and communicates the liquid spray post, and is disposed along a bottom surface and an external sidewall of the top lid. The protection pipeline sleeves on the liquid conveying pipeline. The leak sensor is located between the protection pipeline and the liquid conveying pipeline, and is located under the lowest section of the liquid conveying pipeline.

In some embodiments of the present disclosure, the lowest section of the liquid conveying pipeline is adjacent to a connection point of the bottom surface of the chamber and the external sidewall of the chamber.

In some embodiments of the present disclosure, the liquid conveying pipeline includes a vertical part disposed along the external sidewall of the chamber and a horizontal part disposed along the bottom surface of the chamber, the leak sensor at least partially overlaps with the vertical part of the liquid conveying pipeline in the vertical direction, and at least partially overlaps with the horizontal part of the liquid conveying pipeline in the vertical direction.

In some embodiments of the present disclosure, the wafer cleaning apparatus further includes a liquid compounding controlling module connecting a liquid inlet of the liquid conveying pipeline. The liquid compounding controlling module and the leak sensor are located under the bottom surface of the chamber.

In some embodiments of the present disclosure, the liquid compounding controlling module includes a plurality of flow control valves and a plurality of manifold valves, the manifold valves connect the flow control valves respectively, and the manifold valves are located at an upstream of the liquid conveying pipeline and a downstream of the flow control valves.

One aspect of the present disclosure provides a leakage detection method of a wafer cleaning apparatus.

According to another embodiment of the present disclosure, a leakage detection method of a wafer cleaning apparatus includes: placing a wafer cassette on a rotary chuck in a chamber. A liquid spray post is located in the chamber and faces toward the wafer cassette; rotating the rotary chuck, such that the rotary chuck circles around the liquid spray post; providing a liquid to the liquid spray post through a liquid conveying pipeline; and detecting whether the liquid conveying pipeline has a leakage with a leak sensor located under the lowest section of the liquid conveying pipeline. The leak sensor is located in a protection pipeline sleeving on the liquid conveying pipeline.

In some embodiments of the present disclosure, the leakage detection method of a wafer cleaning apparatus further includes measuring an impedance value of the leak sensor with a monitor apparatus electrically connected to the leak sensor.

In some embodiments of the present disclosure, the leakage detection method of a wafer cleaning apparatus further includes: determining, through the monitor apparatus, the liquid conveying pipeline has no leakage when the impedance value of the leak sensor approaches infinity; and determining, through the monitor apparatus, the liquid conveying pipeline has a leakage when the impedance value of the leak sensor approaches zero.

In some embodiments of the present disclosure, the leakage detection method of a wafer cleaning apparatus further includes: providing the liquid with a liquid compounding controlling module connected to a liquid inlet of the liquid conveying pipeline.

In some embodiments of the present disclosure, the leakage detection method of a wafer cleaning apparatus further includes: controlling and monitoring flow rates of a plurality of acid liquids of the liquid with a plurality of flow control valves of the liquid compounding controlling module; and blending the acid liquids that flow outward from the flow control valves with a plurality of manifold valves to form the liquid.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a wafer cleaning apparatus according to one embodiment of the present disclosure.

FIG. 2 is a local enlarged schematic view of the area near the turning section of the wafer cleaning apparatus of FIG. 1.

FIG. 3 is a schematic view of the wafer cleaning apparatus of FIG. 1 when the lid is opened.

FIG. 4 is a local enlarged schematic view of the liquid compounding controlling module of FIG. 1.

FIG. 5 is a local enlarged schematic view of the area near turning section of the wafer cleaning apparatus according to another embodiment of the present disclosure.

FIG. 6 is a schematic view of rotary chuck connecting to a rotating device of the wafer cleaning apparatus of FIG. 1

FIG. 7 is a flow chart of a leakage detection method of a wafer cleaning apparatus according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the drawings. The spatially relative terms are intended to encompass different orientations of the device in use or operation in addition to the orientation depicted in the drawings. The apparatus may be otherwise oriented (rotated 90 degrees or at other orientations) and the spatially relative descriptors used herein may likewise be interpreted accordingly.

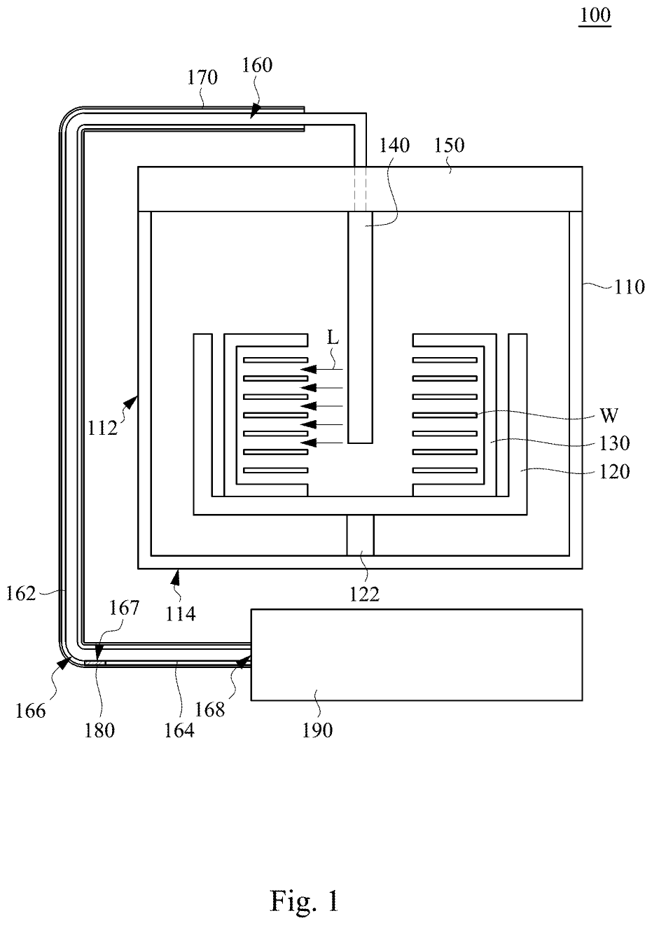

FIG. 1 is a schematic view of a wafer cleaning apparatus 100 according to one embodiment of the present disclosure. Refer to FIG. 1, a wafer cleaning apparatus 100 includes a chamber 110, a rotary chuck 120, a liquid spray post 140, a lid 150, a liquid conveying pipeline 160, a protection pipeline 170, and a leak sensor 180. The rotary chuck 120 is located in the chamber 110, and is configured to attach a wafer cassette 130. The wafer cassette 130 is configured to dispose a plurality of stacked wafer W. In the figure, only two wafer cassettes 130 in the opposite direction is shown, but not limited to it. The liquid spray post 140 can be, for example, surrounded by more than two wafer cassette 130. The wafer W can be semi-manufactured, and contains chemicals (not shown in the figure) to be washed. The chemicals can be, for example, photoresist, but not limited to it. The liquid spray post 140 is located in the chamber 110. The liquid spray post 140 faces the wafer cassette 130 and can spray the spray of the liquid L. The liquid L can be, for example, a chemical liquid (e.g. acid liquid), but not limited to it.

The lid 150 is located on the chamber 110. The liquid spray post 140 is disposed on a bottom surface of the lid 150. The liquid conveying pipeline 160 is located outside the chamber 110 and communicates the liquid spray post 140, and is disposed along a bottom surface 114 of the chamber 110, an external sidewall 112 of the chamber 110 and the lid 150. The protection pipeline 170 sleeves on the liquid conveying pipeline 160. The protection pipeline 170 can protect the liquid conveying pipeline 160 from rupture by external forces and prevent the leakage of the liquid conveying pipeline 160 to an external environment (e.g. the floor) to prevent personnel hazard. The leak sensor 180 is located in the protection pipeline 170, and is located under the lowest section 167 of the liquid conveying pipeline 160. In this embodiment, the lowest section 167 of the liquid conveying pipeline 160 is adjacent to a connection point of the bottom surface 114 of the chamber 110 and the external sidewall 112 of the chamber 110. The leak sensor can determine whether there is liquid L leaked from the liquid conveying pipeline 160 in the protection pipeline 170, and issues a warning signal of leakage.

In particular, since the wafer cleaning apparatus 100 has the protection pipeline 170 that sleeves on the liquid conveying pipeline 160, and the leak sensor 180 is located in the protection pipeline 170 and under the lowest section 167 of the liquid conveying pipeline 160, it not only can prevent the rupture of the liquid conveying pipeline 160 by repeatedly folded, also can monitor whether there is a leakage in the liquid conveying pipeline 160, such that the flow rate can be terminal monitored and make sure that the capacity and the flow rate of the chemical is sufficient through the liquid conveying pipeline 160 and the liquid spray post 140 into the chamber 110, for the washing and the etching of the wafer W, which effectively improves the stability of the fabrication and the yield rate of the products.

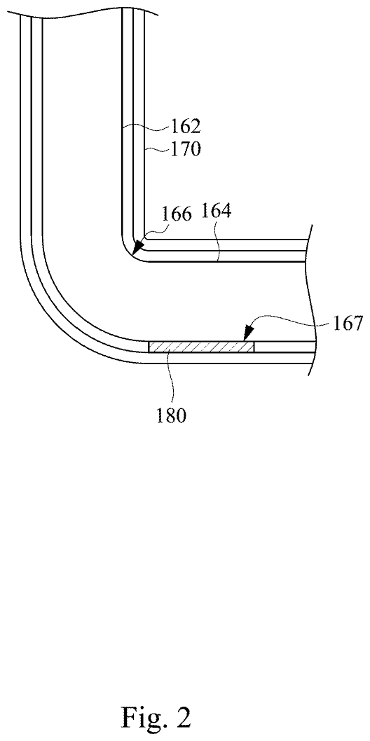

FIG. 2 is a local enlarged schematic view of the area near the turning section 166 of the wafer cleaning apparatus 100 of FIG. 1. Refer to FIG. 1 and FIG. 2, the liquid conveying pipeline 160 includes a vertical part 162 disposed along the external sidewall 112 of the chamber 110, and the leak sensor 180 at least partially overlaps with the vertical part 162 of the liquid conveying pipeline 160 in a vertical direction. Moreover, the liquid conveying pipeline 160 includes a horizontal part 164 disposed along the bottom surface 114 of the chamber 110, and the leak sensor 180 at least partially overlaps with the horizontal part 164 of the liquid conveying pipeline 160 in a vertical direction. In FIG. 2, the lowest section 167 is adjacent to the turning section 166, but the position of the lowest section 167 is not limited to it. In some embodiments, the lowest section 167 can be the turning section 166 or far from the turning section 166. As a result of such a design, if there is a leakage in the liquid conveying pipeline 160, the leaked liquid would shed down or drip down to the leak sensor 180 and could be detected. In addition, the leak sensor 180 is disposed between the liquid conveying pipeline 160 and the protection pipeline 170, which is not only convenient to be disposed, but also able to detect the accumulated (or flowing) liquid under the horizontal part 164 of the liquid conveying pipeline 160.

In this embodiment, the leak sensor 180 is an impedance leak sensor, so an impedance value of the leak sensor 180 can determine whether there is a leakage or not. For example, if the liquid conveying pipeline 160 has no leakage of the liquid L, the impedance value of the leak sensor 180 would approach infinity; if the liquid conveying pipeline 160 has a leakage of liquid L when the impedance value of the leak sensor 180 approaches zero.

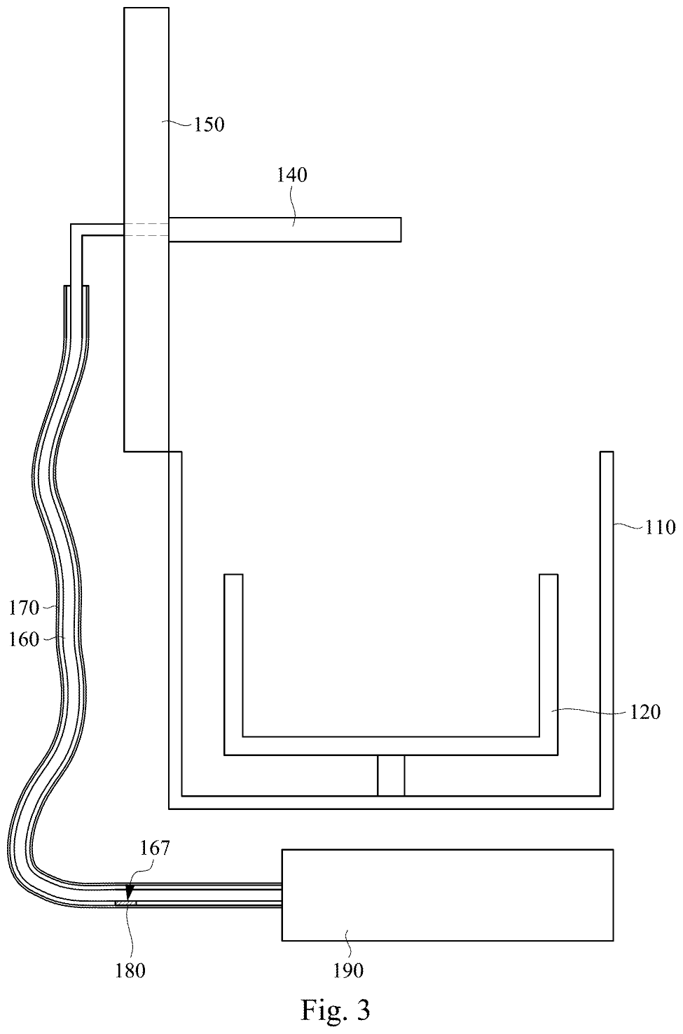

FIG. 3 is a schematic view of the wafer cleaning apparatus 100 of FIG. 1 when the lid 150 is opened. Refer to FIG. 1 and FIG. 3, when the lid 150 is opened and the wafer cassette 130 is removed, various parts of the liquid conveying pipeline 160 and the protection pipeline 170 will be folded. The vertical part 162 of the liquid conveying pipeline 160 and the horizontal part 164 of the liquid conveying pipeline 160 shown in FIG. 1 will also be folded. Since the protection pipeline 170 is therein disposed, the liquid conveying pipeline 160 can be protected and prevent the leakage of the liquid conveying pipeline 160. Moreover, when the lid 150 is opened, if the liquid conveying pipeline 160 leaks the liquid L, the liquid L will flow down along the protection pipeline 170 to the leak sensor 180 located under the lowest section 167, such that the leak sensor 180 can issue a warning signal.

The wafer cleaning apparatus 100 can monitor the situation of leakage through the warning signal of the leak sensor 180, thereby guaranteeing the flow rate of the liquid L that goes into the chamber 110 is sufficient and ensuring the stability of fabrication.

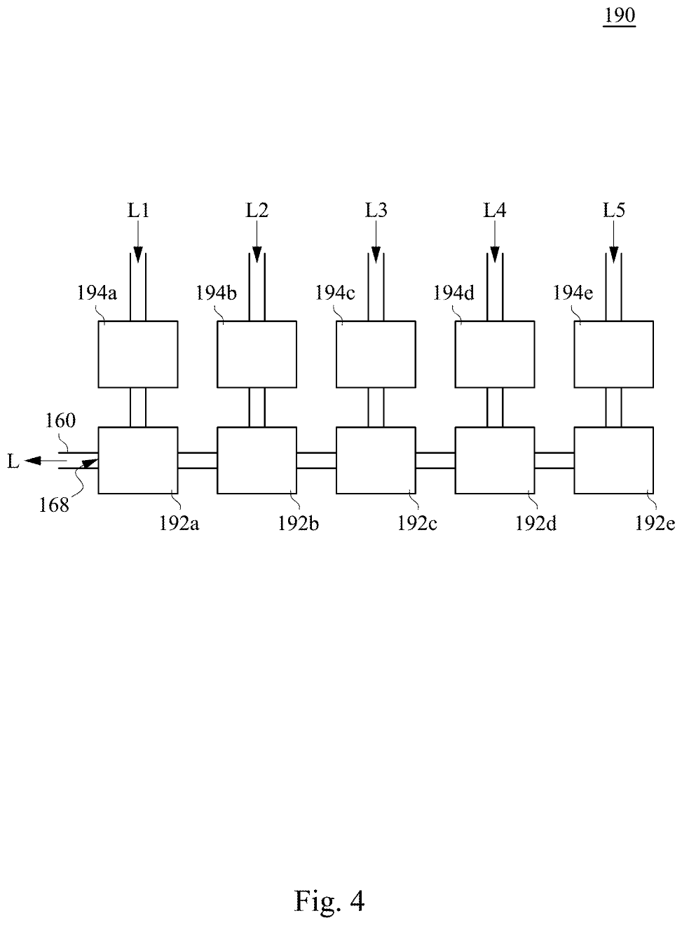

FIG. 4 is a local enlarged schematic view of the liquid compounding controlling module 190 of FIG. 1. Refer to FIG. 1 and FIG. 4, the wafer cleaning apparatus 100 further includes a liquid compounding controlling module 190 connecting a liquid inlet 168 of the liquid conveying pipeline 160. The liquid compounding controlling module 190 and the leak sensor 180 are located under the bottom surface 114 of the chamber 110. The liquid compounding controlling module 190 includes a plurality of manifold valves 192a, 192b, 192c, 192d and 192e and a plurality of flow control valves 194a, 194b, 194c, 194d and 194e. In FIG. 4, the amounts of the manifold valves and the amounts of the flow control valves is five respectively, but not limited to it. The manifold valves 192a, 192b, 192c, 192d and 192e connect the flow control valves 194a, 194b, 194c, 194d and 194e respectively, and the manifold valves 192a, 192b, 192c, 192d and 192e are located at an upstream of the liquid conveying pipeline 160 and a downstream of the flow control valves 194a, 194b, 194c, 194d and 194e. The flow control valves 194a, 194b, 194c, 194d and 194e controls the flow rates of acid liquids L1, L2, L3, L4 and L5 respectively, thereby making different flow rates, types and concentrations of the acid liquids L1, L2, L3, L4 and L5 flows into the manifold valves 192a, 192b, 192c, 192d and 192e, blending and forming the liquid L. The formation of the liquid L can be adjusted according to the need of different fabrication by adjusting the flow rates of the acid liquids L1, L2, L3, L4 and L5. The liquid compounding controlling module 190 sends the liquid L into the liquid conveying pipeline 160 through the liquid inlet 168. In FIG. 4, the amount of the acid liquids is five, but not limited to five.

It is to be noted that the connection relationships, the materials, and the advantages of the elements described above will not be repeated in the following description.

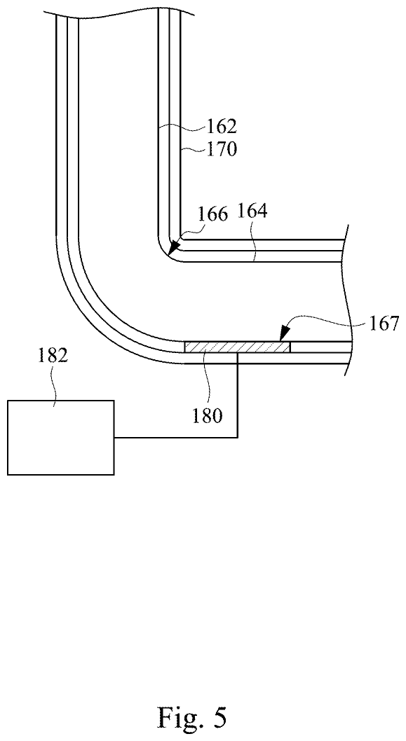

FIG. 5 is a local enlarged schematic view of the area near the turning section 166 of the wafer cleaning apparatus 100 according to another embodiment of the present disclosure. Refer to FIG. 5, the wafer cleaning apparatus 100 of FIG. 1 further includes a monitor apparatus 182 electrically connected to the leak sensor 180 and is configured to monitor an impedance value of the leak sensor 180, and determine whether there is a leakage or not. If the impedance value, measured through the monitor apparatus 182, of the leak sensor 180 approaches infinity, the liquid conveying pipeline 160 is determined to have no leakage of the liquid L. If the impedance value, measured through the monitor apparatus 182, of the leak sensor 180 approaches zero, the liquid conveying pipeline 160 is determined to have a leakage of the liquid L.

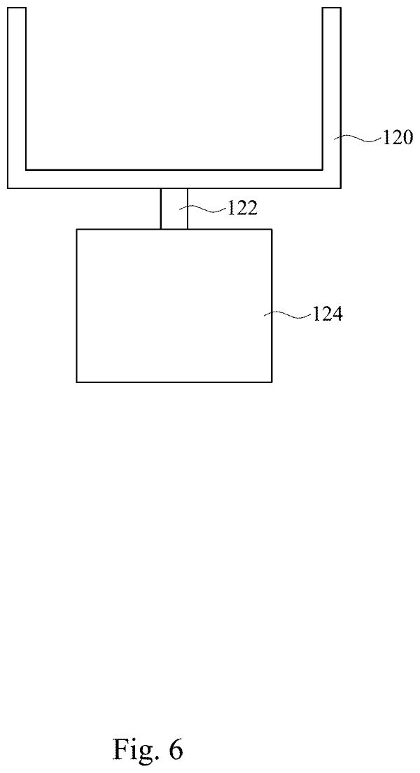

FIG. 6 is a schematic view of rotary chuck 120 connecting to a rotating device 124 of the wafer cleaning apparatus 100 of FIG. 1. Refer to FIG. 1 and FIG. 6, the rotary chuck 120 has a rotation axis 122, the wafer cleaning apparatus 100 further includes a rotating device 124 connected to the rotation axis 122 and configured to rotate the rotary chuck 120 such that the wafer cassette 130 circles around the liquid spray post 140, such that the liquid spray post 140 can remain fixed while cleaning the wafer W disposed on multiple wafer cassettes 130 circles around the liquid spray post 140. In some embodiments, the rotating device can be, for example, a motor.

In the following description, a leakage detecting method of the wafer cleaning apparatus 100 is described.

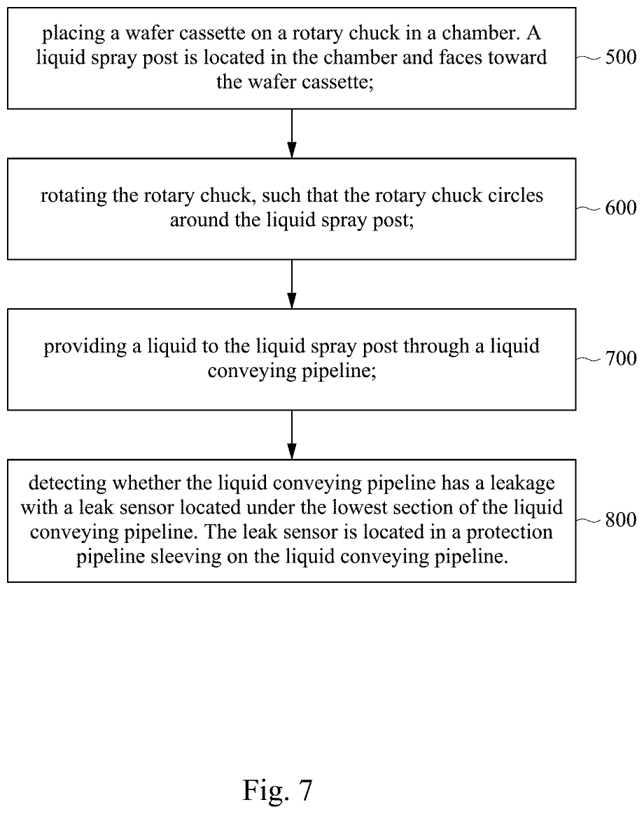

FIG. 7 is a flow chart of a leakage detection method of a wafer cleaning apparatus 100 according to one embodiment of the present disclosure. Refer to FIG. 1 and FIG. 7, the leakage detection method of a wafer cleaning apparatus 100 includes the following steps. In step 500, placing a wafer cassette 130 on a rotary chuck 120 in a chamber 110. A liquid spray post 140 is located in the chamber 110 and faces toward the wafer cassette 130. Followed by step 600, rotating the rotary chuck 120, such that the rotary chuck 120 circles around the liquid spray post 140. Followed by step 700, providing a liquid L to the liquid spray post 140 through a liquid conveying pipeline 160. Followed by step 800, detecting whether the liquid conveying pipeline 160 has a leakage with a leak sensor 180 located under the lowest section 167 of the liquid conveying pipeline 160. The leak sensor 180 is located in a protection pipeline 170 sleeving on the liquid conveying pipeline 160.

Refer to FIG. 1 and FIG. 5, the leakage detection method of a wafer cleaning apparatus 100 further includes measuring an impedance value of the leak sensor 180 with a monitor apparatus 182 electrically connected to the leak sensor 180; determining, through the monitor apparatus 182, the liquid conveying pipeline 160 has no leakage of liquid L when the impedance value of the leak sensor 180 approaches infinity; and determining, through the monitor apparatus 182, the liquid conveying pipeline 160 has a leakage of liquid L when the impedance value of the leak sensor 180 approaches zero. In this way, the impedance value of the leak sensor 180 can be qualitatively measured by the monitor apparatus 182, thereby better keeping track of the situation of leakage.

Refer to FIG. 1, the leakage detection method of a wafer cleaning apparatus 100 further includes providing the liquid L with a liquid compounding controlling module 190 connected to a liquid inlet 168 of the liquid conveying pipeline 160. In this way, the combination of the liquid L can be formed by the liquid compounding controlling module 190.

Refer to FIG. 1 and FIG. 4, the leakage detection method of a wafer cleaning apparatus 100 further includes: controlling and monitoring flow rates of a plurality of acid liquids L1, L2, L3, L4 and L5 of the liquid L with a plurality of flow control valves 194a, 194b, 194c, 194d and 194e of the liquid compounding controlling module 190; and blending the acid liquids L1, L2, L3, L4 and L5 that flow outward from the flow control valves 194a, 194b, 194c, 194d and 194e with a plurality of manifold valves 192a, 192b, 192c, 192d and 192e to form the liquid L. In this way, the acid liquids L1, L2, L3, L4 and L5 that forms the liquid L can be blended precisely in the manifold valves 192a, 192b, 192c, 192d and 192e of the liquid compounding controlling module 190, and monitor the flow rates ratio of the acid liquids L1, L2, L3, L4 and L5 through the flow control valves 194a, 194b, 194c, 194d and 194e to make sure the liquid L can be formed, and provide the liquid L into the liquid conveying pipeline 160 through the liquid inlet 168.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A wafer cleaning apparatus, comprising:
a chamber;
a rotary chuck located in the chamber, configured to dispose a wafer cassette;
a liquid spray post located in the chamber, wherein the liquid spray post faces toward the wafer cassette;
a lid located on the chamber, wherein the liquid spray post is disposed on a bottom surface of the lid;
a liquid conveying pipeline located outside the chamber and communicating the liquid spray post, and disposed along a bottom surface of the chamber, an external sidewall of the chamber and the lid;
a protection pipeline sleeving on the liquid conveying pipeline; and
a leak sensor located in the protection pipeline, and located under the lowest section of the liquid conveying pipeline.

2. The wafer cleaning apparatus of claim 1, wherein the lowest section of the liquid conveying pipeline is adjacent to a connection point of the bottom surface of the chamber and the external sidewall of the chamber.

3. The wafer cleaning apparatus of claim 1, wherein the liquid conveying pipeline comprises a vertical part disposed along the external sidewall of the chamber, and the leak sensor at least partially overlaps with the vertical part of the liquid conveying pipeline in a vertical direction.

4. The wafer cleaning apparatus of claim 1, wherein the liquid conveying pipeline comprises a horizontal part disposed along the bottom surface of the chamber, and the leak sensor at least partially overlaps with the horizontal part of the liquid conveying pipeline in a vertical direction.

5. The wafer cleaning apparatus of claim 1, wherein the leak sensor is an impedance leak sensor.

6. The wafer cleaning apparatus of claim 1, wherein the leak sensor is disposed between the liquid conveying pipeline and the protection pipeline.

7. The wafer cleaning apparatus of claim 1, further comprising:
a liquid compounding controlling module connecting a liquid inlet of the liquid conveying pipeline, wherein the liquid compounding controlling module and the leak sensor are located under the bottom surface of the chamber.

8. The wafer cleaning apparatus of claim 7, wherein the liquid compounding controlling module comprises a plurality of flow control valves and a plurality of manifold valves, the manifold valves connects the flow control valves respectively, and the manifold valves are located at an upstream of the liquid conveying pipeline and a downstream of the flow control valves.

9. The wafer cleaning apparatus of claim 1, further comprising:
a monitor apparatus electrically connected to the leak sensor and configured to monitor an impedance value of the leak sensor.

10. The wafer cleaning apparatus of claim 1, wherein the rotary chuck has a rotation axis, the wafer cleaning apparatus further comprising:
a rotating device connected to the rotation axis and configured to rotate the rotary chuck such that the wafer cassette circles around the liquid spray post.

11. A wafer cleaning apparatus, comprising:
a chamber;
a rotary chuck located in the chamber, configured to dispose a wafer cassette;
a liquid spray post located in the chamber, wherein the liquid spray post faces toward the wafer cassette;
a lid located on the chamber, wherein the liquid spray post is disposed on a bottom surface of the lid;
a liquid conveying pipeline located outside the chamber and communicating the liquid spray post, and disposed along a bottom surface of the chamber, an external sidewall of the chamber and the lid;
a protection pipeline sleeving on the liquid conveying pipeline; and
a leak sensor located between the protection pipeline and the liquid conveying pipeline, and located under the lowest section of the liquid conveying pipeline.

12. The wafer cleaning apparatus of claim 11, wherein the lowest section of the liquid conveying pipeline is adjacent to a connection point of the bottom surface of the chamber and the external sidewall of the chamber.

13. The wafer cleaning apparatus of claim 11, wherein the liquid conveying pipeline comprises a vertical part disposed along the external sidewall of the chamber and a horizontal part disposed along the bottom surface of the chamber, the leak sensor at least partially overlaps with the vertical part of the liquid conveying pipeline in a vertical direction, and at least partially overlaps with the horizontal part of the liquid conveying pipeline in a vertical direction.

14. The wafer cleaning apparatus of claim 11, further comprising:
a liquid compounding controlling module connecting a liquid inlet of the liquid conveying pipeline, wherein the liquid compounding controlling module and the leak sensor are located under the bottom surface of the chamber.

15. The wafer cleaning apparatus of claim 14, wherein the liquid compounding controlling module comprises a plurality of flow control valves and a plurality of manifold valves, the manifold valves connects the flow control valves respectively, and the manifold valves are located at an upstream of the liquid conveying pipeline and a downstream of the flow control valves.

16. A leakage detection method of a wafer cleaning apparatus, comprising:
placing a wafer cassette on a rotary chuck in a chamber, wherein a liquid spray post is located in the chamber and faces toward the wafer cassette;
rotating the rotary chuck, such that the rotary chuck circles around the liquid spray post;
providing a liquid to the liquid spray post through a liquid conveying pipeline; and
detecting whether the liquid conveying pipeline has a leakage with a leak sensor located under the lowest section of the liquid conveying pipeline, wherein the leak sensor is located in a protection pipeline sleeving on the liquid conveying pipeline.

17. The leakage detection method of a wafer cleaning apparatus of claim 16, further comprising:
measuring an impedance value of the leak sensor with a monitor apparatus electrically connected to the leak sensor.

18. The leakage detection method of a wafer cleaning apparatus of claim 17, further comprising:
determining, through the monitor apparatus, the liquid conveying pipeline has no leakage when the impedance value of the leak sensor approaches infinity; and
determining, through the monitor apparatus, the liquid conveying pipeline has a leakage when the impedance value of the leak sensor approaches zero.

19. The leakage detection method of a wafer cleaning apparatus of claim 16, further comprising:
providing the liquid with a liquid compounding controlling module connected to a liquid inlet of the liquid conveying pipeline.

20. The leakage detection method of a wafer cleaning apparatus of claim 19, further comprising:
controlling and monitoring flow rates of a plurality of acid liquids of the liquid with a plurality of flow control valves of the liquid compounding controlling module; and
blending the acid liquids that flow outward from the flow control valves with a plurality of manifold valves to form the liquid.
